(19) United States
(12) Patent Application Publication
(10) Pub. No.: US 2026/0159372 A1
(43) Pub. Date: Jun. 11, 2026

(54) MEMS DEVICE AND METHOD FOR CHARACTERIZING A MEMS DEVICE

(71) Applicant: Infineon Technologies AG, Neubiberg (DE)

(72) Inventors: David BRUNNER, Wien (AT); Stephan Gerhard ALBERT, München (DE)

(21) Appl. No.: 19/181,558

(22) Filed: Apr. 17, 2025

(30) Foreign Application Priority Data
Apr. 26, 2024 (DE) 102024203958.6

(51) Int. Cl. B81B 3/00; G02B 26/08

(52) U.S. Cl. CPC B81B 3/0045; G02B 26/0841; B81B 2201/033; B81B 2201/042; B81B 2203/0136; B81B 2203/04; B81B 2203/058

(57) ABSTRACT

Provided is a MEMS device. The MEMS device includes a stator including a recess. Additionally, the MEMS device includes a rotor arranged in the recess and configured to oscillate about an oscillation axis. The rotor includes first rotor electrodes interdigitated with first stator electrodes and second rotor electrodes interdigitated with second stator electrodes. The first stator electrodes and the second stator electrodes are arranged at opposite sides of the recess. The MEMS device further includes drive circuitry configured to apply electric potentials to the first and second stator electrodes. When the rotor is in a rest position, the drive circuitry is configured to generate the electric potentials to apply a non-zero torque to the rotor to start oscillation of the rotor about the oscillation axis.

### CROSS-REFERENCE TO RELATED APPLICATION

This application claims priority to Germany Patent Application No. 102024203958.6 filed on Apr. 26, 2024, the content of which is incorporated by reference herein in its entirety.

### FIELD

The present disclosure relates to Micro-ElectroMechanical Systems (MEMS). In particular, examples of the present disclosure relate to a MEMS device and a method for characterizing a MEMS device.

### BACKGROUND

Electrostatic MEMS mirrors are typically driven in first-order parametric excitation. This is the most energy efficient operation condition and therefore preferable in operation. However, when the mirror is started from rest position, parametric excitation has a considerable drawback as no net torque is generated by the applied voltage. Only if the actuation voltage is applied at the correct frequency, the rest position gets unstable and the mirror starts to oscillate. The time when the mirror starts to oscillate is rather long and uncertain as it depends highly on variations in the rest position static tilt, which can slightly change at every start and also depends on external influences (e.g., temperature).

Besides long startup times, parametric excitation additionally imposes limitations in the frequency response. The steady state frequency response of a typical MEMS mirror shows a hysteresis between down-and upsweep. In order to reach high amplitudes, the response curve has to be followed, which requires a change of sweep direction at a specific operation point. Also the parametric excitation limits the frequency region where the oscillation can be started.

The discussed drawbacks of the conventional parametric excitation can lead to long test times in production and potentially false device fail detections. In application, the possible startup time of the MEMS mirror is limited by the uncertain and long start of the mirror oscillation.

Hence, there may be a demand to overcome the above drawbacks.

### SUMMARY

This demand is met by the subject-matter of the independent claims. Advantageous implementations are addressed by the dependent claims.

According to a first aspect, the present disclosure provides a MEMS device. The MEMS device includes a stator including a recess. Additionally, the MEMS device includes a rotor arranged in the recess and configured to oscillate about an oscillation axis. The rotor includes first rotor electrodes interdigitated with first stator electrodes and second rotor electrodes interdigitated with second stator electrodes. The first stator electrodes and the second stator electrodes are arranged at opposite sides of the recess. The MEMS device further includes drive circuitry configured to apply electric potentials to the first and second stator electrodes. When the rotor is in a rest position, the drive circuitry is configured to generate the electric potentials to apply a non-zero torque to the rotor to start oscillation of the rotor about the oscillation axis.

According to a second aspect, the present disclosure provides a method for characterizing a MEMS device. The MEMS device includes a stator and a rotor. The rotor is arranged in a recess of the stator and configured to oscillate about an oscillation axis. The rotor includes first rotor electrodes interdigitated with first stator electrodes and second rotor electrodes interdigitated with second stator electrodes. The first stator electrodes and the second stator electrodes are arranged at opposite sides of the recess. The method includes determining whether the rotor is at rest. If it is determined that the rotor is rest, the method further includes concurrently applying oscillating electric potentials to the first and second stator electrodes that are 180° phase-shifted with respect to each other. In addition, the method include sweeping a frequency of the oscillating electric potentials. The method includes measuring a deflection of the rotor about the oscillation axis for the different frequencies of the oscillating electric potentials. Further, the method includes determining a characteristic of the MEMS device based on the measured deflections of the rotor for the different frequencies of the oscillating electric potentials.

According to the proposed technique, a non-zero torque is applied to the rotor via the electric potentials at startup. This leads to a net torque at rest position and significantly improves the startup time and startup frequency region.

### BRIEF DESCRIPTION OF THE DRAWINGS

Some examples of apparatuses and/or methods will be described in the following by way of example only, and with reference to the accompanying figures, in which

FIG. 1 illustrates a sectional view of an example of a MEMS device;

FIG. 2 illustrates an example comparison of startup times for different electric potentials applied to the first and second stator electrodes of the MEMS device illustrated in FIG. 1;

FIG. 3 illustrates an example comparison of steady state frequency responses for different electric potentials applied to the first and second stator electrodes of the MEMS device illustrated in FIG. 1; and

FIG. 4 illustrates a flowchart of an example of a method for characterizing a MEMS device.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

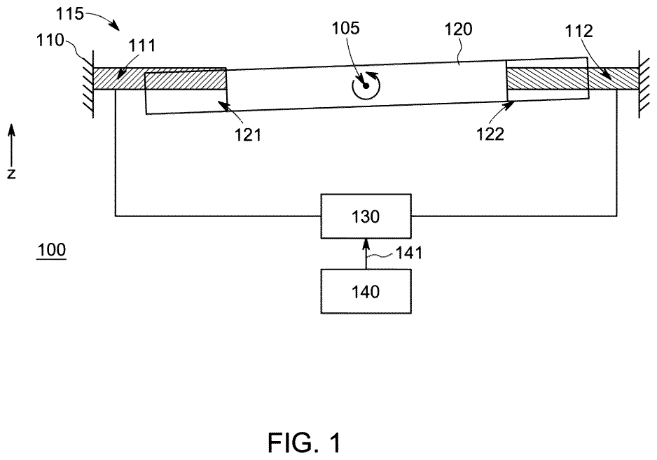

FIG. 1 illustrates sectional view of an example MEMS device 100. The MEMS device comprises a stator 110. The stator 110 is the stationary part (substrate, base) of the MEMS device 100. The stator 110 may be made from various materials such as one or more of semiconductor material (e.g., silicon, polysilicon or silicon carbide), glass, metal, metal alloys and ceramics (e.g., alumina or zirconia). The stator 110 comprises a recess 115. In other words, the recess 115 is formed in the stator 110. The recess 115 extends completely (all the way, entirely) through the stator 110 along a thickness direction z of the stator 110 and the MEMS device 100. The thickness direction z of the stator 110 and the MEMS device 100 extends from a top to a bottom of the stator 110/the MEMS device 100, or vice versa. The recess 115 may exhibit any shape. For example, the recess 115 may be a rectangular, square, circular or oval recess formed in the stator 110.

Additionally, the MEMS device 100 comprises a rotor 120 arranged in the recess 115. The rotor 120 is configured to oscillate about an oscillation axis 105 of the MEMS device 100. The stator 110 serves a mechanical support for the rotor 120. The rotor 120 is suspended from the stator 110 by a suspension structure (not shown in FIG. 1). The suspension structure may comprise one or more of hinges, springs and flexures to allow the rotor 120 to rotate relative to the stator 110 about the oscillation axis 105. The oscillation axis 105 extends perpendicular to the thickness direction z of the stator 110 between opposite side of the recess 115. The rotor 120 may be made from the same materials as the stator 110 or from different materials.

The rotor 120 may exhibit any shape. For example, rotor 120 may exhibit a rectangular, square, circular or oval shape when seen from the top or the bottom of the MEMS device 100. The rotor 120 may exhibit a flat (planar) surface as illustrated in FIG. 1. Alternatively, rotor 120 may exhibit a curved (e.g., spherical, cylindrical, parabolic, convex, concave or freeform) surface.

The rotor 120 comprises first rotor electrodes 121 interdigitated with first stator electrodes 111 of the stator 110. Similarly, the rotor 120 comprises second rotor electrodes 122 interdigitated with second stator electrodes 112 of the stator 110. The first rotor electrodes 121 and the second rotor electrodes 122 are arranged at opposite sides of the rotor 120. Analogously, the first stator electrodes 111 and the second stator electrodes 112 are arranged at opposite sides of the recess 115. The first stator electrodes 111 and the second stator electrodes 112 are formed at opposite sidewalls of the recess 115. The first rotor electrodes 121 and the first stator electrodes 111 are arranged on a first side of the oscillation axis 105 and the second rotor electrodes 122 and the second stator electrodes 112 are arranged on a second side of the oscillation axis 105, which is opposite to the first side of the oscillation axis 105. The first rotor electrodes 121 and the second rotor electrodes 122 may be formed symmetrically with respect to the oscillation axis 105.

In the example of FIG. 1, only a single first rotor electrode, a single second rotor electrode, a single first stator electrode and a single second stator electrode are illustrated due to the chosen perspective. In general, the rotor 120 may comprise any number N≥2 of first rotor electrodes 121 and any number M≥2 of second rotor electrodes 122. The number of N of first rotor electrodes 121 may be equal to or be different from the number M of second rotor electrodes 122. Analogously, the stator 110 may comprise any number K≥2 of first stator electrodes 111 and any number L≥2 of second stator electrodes 112. The number of K of first stator electrodes 111 may be equal to or be different from the number L of second stator electrodes 112. The first and second rotor electrodes 121 and 122 form a comb drive with the first and second stator electrodes 111 and 112.

The first and second rotor electrodes 121 as well as the first and second stator electrodes 111 and 112 are made from electrically conductive material (e.g., one or more of semiconductor material, metal and metal alloys).

An asymmetry is introduced in the MEMS device 100 by the first and second stator electrodes 111 and 112. For example, the asymmetry may be introduced by the first and second stator electrodes 111 and 112 not having the same thickness as the first and second rotor electrodes 121 and 122. In the example of FIG. 1, the thickness of the first and second rotor electrodes 121 and 122 is different from the thickness of the first and second stator electrodes 111 and 112. Alternatively or additionally, the asymmetry may be introduced by lifting the first and second stator electrodes 111 and 112 relative to the first and second rotor electrodes 121 and 122. In other words, when the rotor 120 is in a rest position, the extension of the first and second stator electrodes 111 and 112 along the thickness direction z of the MEMS device 100 may be different from the extension of the first and second rotor electrodes 121 and 122 along the thickness direction z of the MEMS device 100. The rest position of the rotor 120 is (refers to) the default or initial orientation of the rotor 120 when no external forces are applied to actuate or move it. In other words, it is the position where the rotor 120 comes to rest naturally. For example, the rest position of the rotor 120 may be determined by the mechanical design of the rotor 120 and the suspension structure as well as the balance of forces acting on it. The asymmetry is beneficial in in terms of manufacturing complexity and rotor position sensing.

The MEMS device 100 further comprises drive circuitry 130 configured to apply electric potentials to the first and second stator electrodes 111 and 112 for driving the rotor 120 to oscillate about the oscillation axis 105. In the example of FIG. 1, the drive circuitry 130 is illustrated as an element separate from the stator 110. However, the present disclosure is not limited thereto. In other examples, the drive circuitry 130 may be implemented in or on the stator 110. For example, the drive circuitry 130 may be electrically coupled to the first and second stator electrodes 111 and 112 via a plurality of conductive paths, traces or channels.

When the rotor 120 is in the rest position, the drive circuitry 130 is configured to generate the electric potentials to apply a non-zero torque to the rotor 120 to start oscillation of the rotor 120 about the oscillation axis 105. In other words, when the rotor 120 is in the rest position, the drive circuitry 130 is configured to generate the electric potentials such that a non-zero torque is applied to the rotor 120 in order to cause the rotor 120 to start oscillating about the oscillation axis 105.

When the rotor 120 is in the rest position, the drive circuitry 130 causes a non-zero torque (net torque) on the rotor 120 such that the rotor 120 starts oscillating about the oscillation axis 105. This significantly improves the startup time and startup frequency region of the MEMS device compared to conventional MEMS devices using conventional parametric excitation at startup of the MEMS device.

The electrical potentials applied to the first and second stator electrodes 111 and 112 may be configured in various ways to cause application of a non-zero torque to the rotor 120 when the rotor 120 is in the rest position. In the following, a few example configurations of the electrical potentials applied to the first and second stator electrodes 111 and 112 will be described in detail. However, it is to be noted that the present disclosure is not limited thereto. Other configurations causing a non-zero torque on the rotor 120 when the rotor 120 is in the rest position may be used as well.

When the rotor 120 is in the rest position, the drive circuitry 120 may be configured to concurrently apply a first electric potential to the first stator electrodes 111 and a second electric potential to the second stator electrodes 112. The first electric potential is different from the second electric potential. The difference between the first electric potential and the second electric potential causes the non-zero torque on the rotor 120 in the rest position.

The first electric potential and the second electric potential may be configured in various ways to cause the non-zero torque on the rotor 120 in the rest position.

For example, the first and second electric potentials may be periodic electric potentials with different duty cycles. The duty cycle is the ratio of the active time (the time during which the waveform of the electric potential is high) to the total period of the waveform. In other words, the waveforms of the first and second electric potentials may repeat periodically but have varying ratios of high potential time to total cycle time.

In alternative examples, the first electric potential may be a constant electrical potential (e.g., the first electrical potential does not change over time) and the second electric potential may be an oscillating electric potential (e.g., a time-varying electrical potential changing magnitude and optionally polarity over time). The second electrical potential may be a periodic electric potential but need not.

In further alternative examples, the first and second electric potentials may both be oscillating electric potentials that are phase-shifted with respect to each other. In other words, the first and second electric potentials may undergo oscillations and their waveforms may offset in time relative to each other. The first and second electric potentials may be periodic electric potentials but need not. The first and second electric potentials may be phase shifted by any phase value different from z·360° with z=0, 1, 2, . . . For example, the first and second electric potentials may be phase-shifted by 180° with respect to each other. A (oscillation) frequency of the first and second electric potentials may be equal to a target oscillation frequency of the rotor 120. That target oscillation frequency of the rotor 120 is (refers to) the desired frequency at which the rotor 120 oscillates (is to oscillate) about the oscillation axis 105.

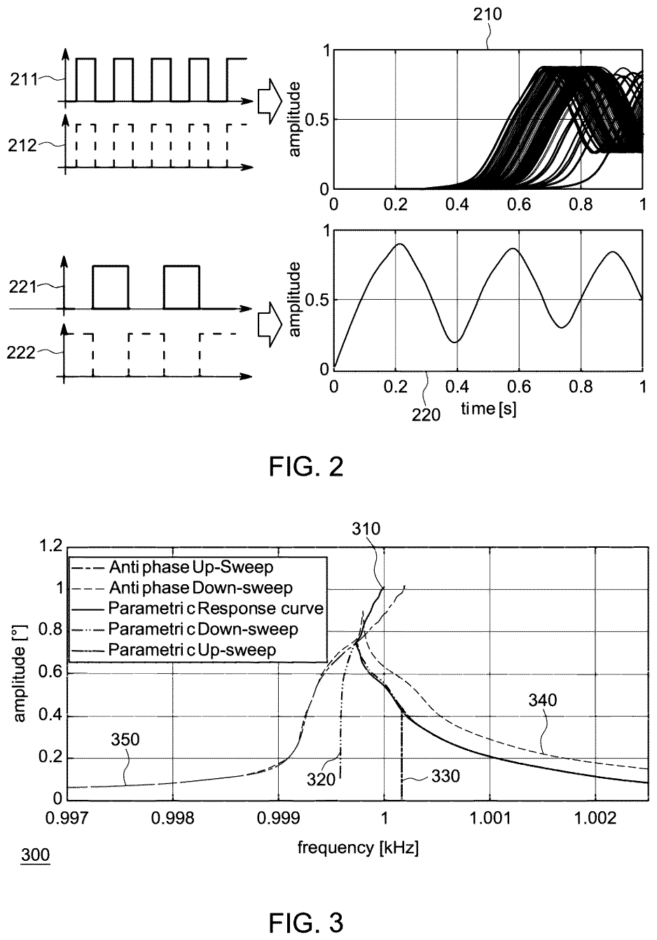

FIG. 2 example illustrates the beneficial effect on the startup time when using first and second electric potentials that are phase-shifted by 180° with respect to each other and that exhibit an (oscillation) frequency equal to the target oscillation frequency of the rotor 120.

As a reference, FIG. 2 illustrates in the upper left part the waveforms of the electric potentials 211 and 212 applied to the first and second stator electrodes 111 and 112 by the driver circuitry 130 according to conventional first-order parametric excitation. The electric potentials 211 and 212 are in phase and have twice the target oscillation frequency of the rotor 120. In the upper right part, the corresponding startup behavior of the MEMS device 100 is illustrated in diagram 210 for 100 consecutive startups of the MEMS device 100. The abscissa denotes time and the ordinate denotes the normalized deflection amplitude of the rotor 120. The normalized deflection amplitude of the rotor 120 is measured in each rotor swing and plotted over time. The actuation is started at time 0. As can be seen from diagram 210, it takes time until the rotor 120 starts to oscillate. Furthermore, there's a high fluctuation in the startup time of the rotor 120.

FIG. 2 illustrates in the lower left part the waveforms of the electric potentials 221 and 222 applied to the first and second stator electrodes 111 and 112 by the driver circuitry 130 according to the proposed technology. The electric potentials 221 and 222 are phase-shifted by 180° with respect to each other and exhibit an (oscillation) frequency equal to the target oscillation frequency of the rotor 120. The corresponding startup behavior of the MEMS device 100 is illustrated in diagram 220 for 100 consecutive startups of the MEMS device 100 in the lower right part of FIG. 2. Like in diagram 210, the abscissa denotes time and the ordinate denotes the normalized deflection amplitude of the rotor 120. The actuation is again started at time 0. As can be seen from diagram 220, the rotor 120 starts to oscillate right away-without any significant delay like for conventional first-order parametric excitation. Furthermore, there's almost no variation in the startup time of the rotor 120 for consecutive startups. Accordingly, a specified startup time may be reliably met.

FIG. 3 further illustrates a diagram 300 showing an example comparison of steady state frequency responses of the MEMS device 100 when driven as described above with reference to FIG. 2. The abscissa denotes the oscillation frequency of the rotor 120 in kHz and the ordinate denotes the deflection amplitude of the rotor 120 in degrees (°).

Three curves 310, 320 and 330 are shown for reference. The curve 310 depicts the parametric response of the MEMS device 100. The curve 320 depicts the response of the MEMS device 100 for a down-sweep of the rotor 120's oscillation frequency with conventional first-order parametric excitation (e.g., electric potentials that are in phase). The curve 330 depicts the response of the MEMS device 100 for an up-sweep of the rotor 120's oscillation frequency with conventional first-order parametric excitation.

Curve 340 depicts the response of the MEMS device 100 for a down-sweep of the rotor 120's oscillation frequency with electric potentials that are phase-shifted by 180°. Curve 350 depicts the response of the MEMS device 100 for an up-sweep of the rotor 120′s oscillation frequency with electric potentials that are phase-shifted by 180°.

It can be seen from the curves 340 and 350 that the hysteresis between up-and down-sweep is not present for the antiphase excitation with electric potentials that are phase-shifted by 180°. Furthermore, a high amplitude can be reached by applying an upsweep only. This simplifies the method to reach high amplitudes as no sweep direction change is necessary like with conventional first-order parametric excitation. In order to reach high amplitudes the response curve 310 has to be followed. This requires a change of seep direction at a specific operation point as can be seen form the curves 320 and 330. Furthermore, the oscillation of the rotor 120 may be started in a much wider frequency region with the antiphase excitation compared to the parametric excitation. For example, the frequency region in which the oscillation of the rotor 120 may be started with the antiphase excitation may be up to 2.5 times greater than frequency region in which the oscillation of the rotor 120 may be started with parametric excitation. The response with the antiphase excitation is never strictly 0°, whereas there are only certain (small) frequency ranges at which a response greater than 0° is achieved for parametric excitation.

Returning to FIG. 1, the drive circuitry 130 may change the oscillating electric potentials to the first and second stator electrodes 111 and 112 after startup of the rotor 120. For example, when a predefined criterion is met, the drive circuitry 130 may configured to switch to concurrently applying oscillating electric potentials to the first and second stator electrodes 111 and 112 that are in phase. The frequency of the oscillating electric potentials that are in phase may be twice the target oscillation frequency of the rotor 120. In other words, the drive circuitry 130 may configured to switch to first-order parametric excitation of the rotor 120 when the predefined criterion is met. First-order parametric excitation is the most energy efficient operation condition and therefore preferable in operation (e.g., after startup).

The predefined criterion may be manifold. For example, the predefined criterion may be related to the deflection of the rotor 120. The MEMS 100 may, e.g., further comprise a sensor 140 configured to generate a measurement signal 141 indicative of a measured deflection of the rotor 120. The sensor 140 may measure the deflection of the rotor 120 according to known measurement principles. Accordingly, the drive circuitry 130 may be configured to determine whether the predefined criterion is met based on the measurement signal 141. For example, the drive circuitry 130 may be configured to determine that the predefined criterion is met if the measured deflection of the rotor 120 is greater than a predefined threshold value. The threshold value may, e.g., depend on the design of the MEMS device 100. For example, the threshold value may be at minimum 0.2° and be at maximum 1°. In other examples, one or more displacement currents caused by the change in actuator capacitance due to the movement of the rotor 120 may be measured by the sensor 140 to indicate the measured deflection of the rotor 120. If the one or more measured displacement currents indicated by the measurement signal 141 are greater than a noise amplitude, the drive circuitry 130 may be configured to determine that the predefined criterion is met. However, it is to be noted that the present disclosure is not limited to the aforementioned examples. Other suitable criteria may be used instead.

In the example of FIG. 1, the sensor 140 is illustrated as an element separate from the stator 110 and the rotor 120. However, the present disclosure is not limited thereto. In other examples, the sensor 140 may be implemented in or on the stator 110. For example, the sensor 140 may be electrically coupled to the drive circuitry 130 via one or more conductive paths, traces or channels.

According to examples of the present disclosure, the MEMS device 100 may be an electrostatic (resonant) MEMS device. In other words, a Quality factor (Q factor) of the MEMS device 100 may be 5000 or more. The Q factor quantifies the sharpness of the resonance peak of the MEMS device 100's oscillatory response. For example, the Q factor may be defined as the ratio of the energy stored in the MEMS device 100 to the energy dissipated per cycle of oscillation. Additionally or alternatively, an actuator torque-to-oscillator stiffness ratio of the MEMS device 100 may be less than 2 mrad. The actuator torque-to-oscillator stiffness ratio denotes the balance between the torque generated by the actuator (e.g., the comb drive) and the stiffness of the MEMS device 100's oscillatory system (e.g., the MEMS device 100's suspension structure).

The MEMS device 100 may be used in various applications. For example, a mirror may be formed on a surface of the rotor 120. In other words, the MEMS device 100 may be a MEMS mirror. Examples of the present disclosure may provide antiphase drive for electrostatic MEMS mirrors with asymmetric comb electrodes design. However, the MEMS device 100 may be used for other applications as well.

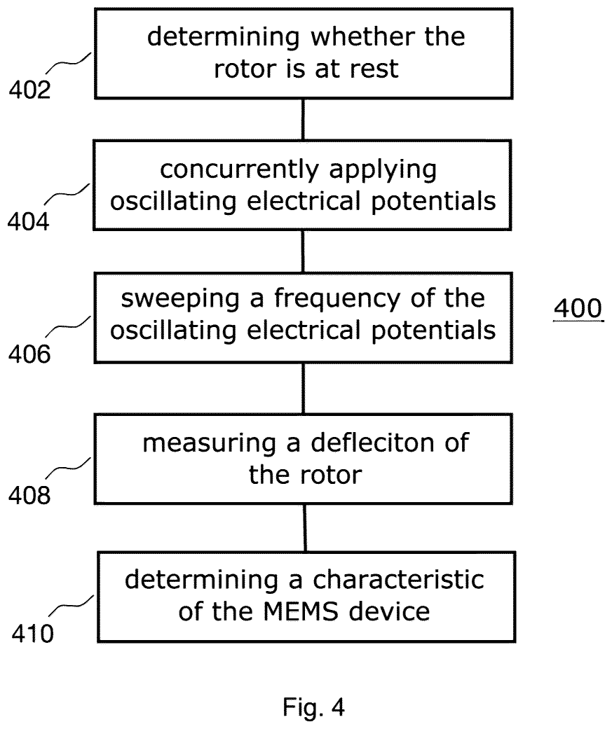

The above-described antiphase drive at startup may further be used for characterizing MEMS devices. FIG. 4 illustrates a flowchart of an example method 400 for characterizing a MEMS device. The MEMS device comprises a stator and a rotor. The rotor is arranged in a recess of the stator and configured to oscillate about an oscillation axis. The rotor comprises first rotor electrodes interdigitated with first stator electrodes and second rotor electrodes interdigitated with second stator electrodes. The first stator electrodes and the second stator electrodes are arranged at opposite sides of the recess.

The method 400 comprises determining 402 whether the rotor is at rest. For example, a position and/or an orientation of the rotor may be measured via one or more sensors according to known measurement principes. The measured position and/or orientation of the rotor may, e.g., be compared to reference values to determine whether the rotor is at rest. Alternatively or additionally, a variation of the measured position and/or orientation of the rotor over time may be analyzed to determine whether the rotor is at rest.

If it is determined that the rotor is rest, the method 400 further comprises concurrently applying 404 oscillating electric potentials to the first and second stator electrodes that are 180° phase-shifted with respect to each other. In addition, the method 400 comprise sweeping 406, across different frequencies, a frequency of the oscillating electric potentials. The frequency of the oscillating electric potentials may, e.g., be up-swept or down-swept across the different frequencies. For example, the frequency of the oscillating electric potentials may be swept at a rate of at least 100 Hz/s.

The method 400 comprises measuring 408 a deflection of the rotor about the oscillation axis for the different frequencies of the oscillating electric potentials. The deflection of the rotor about the oscillation axis may be measured according to known measurement principes. Further, the method 400 comprises determining 410 a characteristic of the MEMS device based on the measured deflections of the rotor for the different frequencies of the oscillating electric potentials.

The method 400 allows to characterize the MEMS device with a significantly improved startup time and startup frequency region due to the application of a non-zero torque to the rotor via the electric potentials. For example, in high-volume production of MEMS devices, the method 400 may allow to significantly reduce the required time for characterization of the individual MEMS device due to the improved startup time and startup frequency region. This may help reduce the cost of producing a single MEMS device. Further, as there's almost no variation in the startup time of the rotor across different MEMS devices due to the anti-phase excitation of the rotor, wrong fail detections may be avoided and, hence, a production yield be increased.

The characteristic may be manifold. For example, the characteristic may be a frequency at which the MEMS device oscillates with a stable amplitude.

More details and aspects of the method 400 are explained in connection with the proposed technique or one or more example described above or below. The method 400 may comprise one or more additional optional features corresponding to one or more aspects of the proposed technique, or one or more example described above or below.

For example, the MEMS device may exhibit an asymmetry-analogously to what is described above. Accordingly, a thickness of the first and second rotor electrodes may be different from a thickness of the first and second stator electrodes. Alternatively or additionally, when the rotor is in the rest position, an extension of the first and second stator electrodes along a thickness direction of the MEMS device may be different from an extension of the first and second rotor electrodes along the thickness direction of the MEMS device.

The MEMS device characterized with the method 400 may be used for various applications. For example, the MEMS device characterized with the method 400 may be a MEMS mirror. In other words, a mirror may be formed on a surface of the rotor.

### ASPECTS

The aspects described herein may be summarized as follows:
An aspect (e.g., aspect 1) relates to a MEMS device. The MEMS device comprises a stator comprising a recess. Additionally, the MEMS device comprises a rotor arranged in the recess and configured to oscillate about an oscillation axis. The rotor comprises first rotor electrodes interdigitated with first stator electrodes and second rotor electrodes interdigitated with second stator electrodes. The first stator electrodes and the second stator electrodes are arranged at opposite sides of the recess. The MEMS device further comprises drive circuitry configured to apply electric potentials to the first and second stator electrodes. When the rotor is in a rest position, the drive circuitry is configured to generate the electric potentials to apply a non-zero torque to the rotor to start oscillation of the rotor about the oscillation axis.
Another aspect (e.g., aspect 2) relates to a previous aspect (e.g., aspect 1) or to any other aspect, wherein a thickness of the first and second rotor electrodes is different from a thickness of the first and second stator electrodes, and/or wherein, when the rotor is in the rest position, an extension of the first and second stator electrodes along a thickness direction of the MEMS device is different from an extension of the first and second rotor electrodes along the thickness direction of the MEMS device.
Another aspect (e.g., aspect 3) relates to a previous aspect (e.g., one of the aspects 1 or 2) or to any other aspect, wherein, when the rotor is in the rest position, the drive circuitry is configured to concurrently apply a first electric potential to the first stator electrodes and a second electric potential to the second stator electrodes, wherein the first electric potential is different from the second electric potential.
Another aspect (e.g., aspect 4) relates to a previous aspect (e.g., aspect 3) or to any other aspect, wherein the first electric potential is a constant electrical potential and the second electric potential is an oscillating electric potential.
Another aspect (e.g., aspect 5) relates to a previous aspect (e.g., aspect 3) or to any other aspect, wherein the first and second electric potentials are oscillating electric potentials that are phase-shifted with respect to each other.
Another aspect (e.g., aspect 6) relates to a previous aspect (e.g., aspect 5) or to any other aspect, wherein the first and second electric potentials are phase-shifted by 180° with respect to each other.
Another aspect (e.g., aspect 7) relates to a previous aspect (e.g., one of the aspects 5 or 6) or to any other aspect, wherein a frequency of the first and second electric potentials is equal to a target oscillation frequency of the rotor.
Another aspect (e.g., aspect 8) relates to a previous aspect (e.g., aspect 3) or to any other aspect, wherein the first and second electric potentials are periodic electric potentials with different duty cycles.
Another aspect (e.g., aspect 9) relates to a previous aspect (e.g., one of the aspects 1 to 9) or to any other aspect, wherein, when a predefined criterion is met, the drive circuitry is configured to switch to concurrently applying oscillating electric potentials to the first and second stator electrodes that are in phase.
Another aspect (e.g., aspect 10) relates to a previous aspect (e.g., aspect 9) or to any other aspect, wherein a frequency of the oscillating electric potentials that are in phase is twice a target oscillation frequency of the rotor.
Another aspect (e.g., aspect 11) relates to a previous aspect (e.g., one of the aspects 9 or 10) or to any other aspect, further comprising a sensor configured to generate a measurement signal indicative of a measured deflection of the rotor, and wherein the drive circuitry is configured to determine whether the predefined criterion is met based on the measurement signal.
Another aspect (e.g., aspect 12) relates to a previous aspect (e.g., one of the aspects 1 to 11) or to any other aspect, wherein an actuator torque-to-oscillator stiffness ratio of the MEMS device is less than 2 mrad.
Another aspect (e.g., aspect 13) relates to a previous aspect (e.g., one of the aspects 1 to 12) or to any other aspect, wherein a Q factor of the MEMS device is 5000 or more.
Another aspect (e.g., aspect 14) relates to a previous aspect (e.g., one of the aspects 1 to 13) or to any other aspect, wherein the first and second rotor electrodes form a comb drive with the first and second stator electrodes.
Another aspect (e.g., aspect 15) relates to a previous aspect (e.g., one of the aspects 1 to 14) or to any other aspect, wherein a mirror is formed on a surface of the rotor.
An aspect (e.g., aspect 16) relates to a method for characterizing a MEMS device. The MEMS device comprises a stator and a rotor. The rotor is arranged in a recess of the stator and configured to oscillate about an oscillation axis. The rotor comprises first rotor electrodes interdigitated with first stator electrodes and second rotor electrodes interdigitated with second stator electrodes. The first stator electrodes and the second stator electrodes are arranged at opposite sides of the recess. The method comprises determining whether the rotor is at rest. If it is determined that the rotor is rest, the method further comprises concurrently applying oscillating electric potentials to the first and second stator electrodes that are 180° phase-shifted with respect to each other. In addition, the method comprise sweeping a frequency of the oscillating electric potentials. The method comprises measuring a deflection of the rotor about the oscillation axis for the different frequencies of the oscillating electric potentials. Further, the method comprises determining a characteristic of the MEMS device based on the measured deflections of the rotor for the different frequencies of the oscillating electric potentials.
Another aspect (e.g., aspect 17) relates to a previous aspect (e.g., aspect 16) or to any other aspect, wherein the frequency of the oscillating electric potentials is swept at a rate of at least 100 Hz/s.
Another aspect (e.g., aspect 18) relates to a previous aspect (e.g., one of the aspects 16 or 17) or to any other aspect, wherein the characteristic is a frequency at which the MEMS device oscillates with a stable amplitude.
Another aspect (e.g., aspect 19) relates to a previous aspect (e.g., one of the aspects 16 to 18) or to any other aspect, wherein a thickness of the first and second rotor electrodes is different from a thickness of the first and second stator electrodes, and/or wherein, when the rotor is in the rest position, an extension of the first and second stator electrodes along a thickness direction of the MEMS device is different from an extension of the first and second rotor electrodes along the thickness direction of the MEMS device.
Another aspect (e.g., aspect 20) relates to a previous aspect (e.g., one of the aspects 16 to 19) or to any other aspect, wherein a mirror is formed on a surface of the rotor.
The aspects and features described in relation to a particular one of the previous aspects may also be combined with one or more of the further aspects to replace an identical or similar feature of that further aspect or to additionally introduce the features into the further aspect.
It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further aspects, a single step, function, process or operation may include and/or be broken up into several sub-steps,-functions,-processes or-operations.

If some aspects have been described in relation to a device or system, these aspects should also be understood as a description of the corresponding method. For aspect, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate aspect. It should also be noted that although in the claims a dependent claim refers to a particular combination with one or more other claims, other aspects may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A Micro-ElectroMechanical Systems (MEMS) device comprising:
a stator comprising a recess;
a rotor arranged in the recess and configured to oscillate about an oscillation axis, wherein the rotor comprises first rotor electrodes interdigitated with first stator electrodes, and second rotor electrodes interdigitated with second stator electrodes, wherein the first stator electrodes and the second stator electrodes are arranged at opposite sides of the recess; and
drive circuitry configured to apply electric potentials to the first stator electrodes and the second stator electrodes,
wherein, when the rotor is in a rest position, the drive circuitry is configured to generate the electric potentials to apply a non-zero torque to the rotor to start oscillation of the rotor about the oscillation axis.

2. The MEMS device of claim 1,
wherein a thickness of the first rotor electrodes and the second rotor electrodes is different from a thickness of the first stator electrodes and the second stator electrodes, and/or
wherein, when the rotor is in the rest position, an extension of the first stator electrodes and the second stator electrodes along a thickness direction of the MEMS device is different from an extension of the first rotor electrodes and the second rotor electrodes along the thickness direction of the MEMS device.

3. The MEMS device of claim 1,
wherein, when the rotor is in the rest position, the drive circuitry is configured to concurrently apply a first electric potential to the first stator electrodes and a second electric potential to the second stator electrodes, and
wherein the first electric potential is different from the second electric potential.

4. The MEMS device of claim 3, wherein the first electric potential is a constant electrical potential and the second electric potential is an oscillating electric potential.

5. The MEMS device of claim 3, wherein the first electric potential and the second electric potential are oscillating electric potentials that are phase-shifted with respect to each other.

6. The MEMS device of claim 5, wherein the first electric potential and the second electric potential are phase-shifted by 180° with respect to each other.

7. The MEMS device of claim 5, wherein a frequency of the first electric potential and second electric potential is equal to a target oscillation frequency of the rotor.

8. The MEMS device of claim 3, wherein the first electric potential and the second electric potential are periodic electric potentials with different duty cycles.

9. The MEMS device of claim 1, wherein, when a predefined criterion is met, the drive circuitry is configured to switch to concurrently applying oscillating electric potentials to the first stator electrodes and the second stator electrodes that are in phase.

10. The MEMS device of claim 9, wherein a frequency of the oscillating electric potentials that are in phase is twice a target oscillation frequency of the rotor.

11. The MEMS device of claim 9, further comprising:
a sensor configured to generate a measurement signal indicative of a measured deflection of the rotor, and
wherein the drive circuitry is configured to determine whether the predefined criterion is met based on the measurement signal.

12. The MEMS device of claim 1, wherein an actuator torque-to-oscillator stiffness ratio of the MEMS device is less than 2 mrad.

13. The MEMS device of claim 1, wherein a Q factor of the MEMS device is 5000 or more.

14. The MEMS device according to claim 1, wherein the first rotor electrodes and the second rotor electrodes form a comb drive with the first stator electrodes and the second stator electrodes.

15. The MEMS device according to claim 1, wherein a mirror is formed on a surface of the rotor.

16. A method for characterizing a Micro-ElectroMechanical Systems (MEMS) device, the MEMS device comprising:
a stator and a rotor, wherein the rotor is arranged in a recess of the stator and configured to oscillate about an oscillation axis, wherein the rotor comprises first rotor electrodes interdigitated with first stator electrodes and second rotor electrodes interdigitated with second stator electrodes, wherein the first stator electrodes and the second stator electrodes are arranged at opposite sides of the recess, the method comprising:
determining whether the rotor is at rest
if it is determined that the rotor is rest, concurrently applying oscillating electric potentials to the first stator electrodes and second stator electrodes that are 180° phase-shifted with respect to each other;
sweeping, across different frequencies, a frequency of the oscillating electric potentials;
measuring a deflection of the rotor about the oscillation axis for the different frequencies of the oscillating electric potentials; and
determining a characteristic of the MEMS device based on the measured deflections of the rotor for the different frequencies of the oscillating electric potentials.

17. The method of claim 16, wherein the frequency of the oscillating electric potentials is swept at a rate of at least 100 Hz/s.

18. The method of claim 16, wherein the characteristic is a frequency at which the MEMS device oscillates with a stable amplitude.

19. The method of claim 16,
wherein a thickness of the first rotor electrodes and the second rotor electrodes is different from a thickness of the first stator electrodes and the second stator electrodes, and/or
wherein, when the rotor is in the rest position, an extension of the first stator electrodes and the second stator electrodes along a thickness direction of the MEMS device is different from an extension of the first rotor electrodes and the second rotor electrodes along the thickness direction of the MEMS device.

20. The method of claim 16, wherein a mirror is formed on a surface of the rotor.
